(19) United States
(12) Patent Application Publication
(10) Pub. No.: US 2007/0268941 A1
(43) Pub. Date: Nov. 22, 2007

(54) VERTICAL EXTERNAL CAVITY SURFACE EMITTING LASER AND METHOD THEREOF

(75) Inventors: Gi-bum Kim, Yongin-si (KR); Soo-haeng Cho, Yongin-si (KR); Taek Kim, Yongin-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/668,754

(22) Filed: Jan. 30, 2007

(30) Foreign Application Priority Data
May 16, 2006 (KR) 1020060043942

(51) Int. Cl. H01S 3/10; H01S 5/00; H01S 3/093

(52) U.S. Cl. 372/22; 372/50.23; 372/50.124; 372/72

(57) ABSTRACT

A vertical external cavity surface emitting laser (“VECSEL”). The VECSEL includes a light-emitting device, a second harmonic generation (“SHG”) crystal and an external cavity mirror. The light-emitting device includes a mirror layer limiting a resonance region, an active layer generating light, a heat spreader dissipating heat generated in the active layer, and a micro lens coupled to the heat spreader and including a convex outer surface to focus light. The second harmonic generation crystal converts the frequency of light focused by the micro lens. The external cavity mirror transmits the light converted by the second harmonic generation crystal and outputs the transmitted light as laser light, and reflects unconverted light back to the mirror layer to resonate the light.

This application claims priority to Korean Patent Application No. 10-2006-0043942, filed on May 16, 2006, and all the benefits accruing therefrom under 35 U.S.C. §119, the disclosure of which is incorporated herein in its entirety by reference.

### BACKGROUND OF THE INVENTION

1. Field of the Invention

The present invention relates to a vertical external cavity surface emitting laser (“VECSEL”), and more particularly, to a VECSEL with an increased output and components that can be easily aligned for assembly, and that can readily be compacted.

2. Description of the Related Art

A vertical external cavity surface emitting laser (“VECSEL”) is a laser device that substitutes an upper mirror of a vertical cavity surface emitting laser (“VCSEL”) with an external cavity mirror to increase a gain region and to obtain a higher output by several to several tens of watts or more.

FIG. 1 is a vertical sectional view of a conventional VECSEL. Referring to FIG. 1, the conventional VECSEL includes a pump laser diode (“LD”) 10 for emitting pumping light (P), a focusing lens 15 for focusing the pumping light (P), a light-emitting medium 25 of a light emitting device 20 for generating a predetermined wavelength of light that is excited by the pump LD 10, and an external cavity mirror 50 disposed to face the light-emitting medium 25 at a predetermined distance therefrom.

The pump LD 10 is obliquely disposed with respect to a front of the light-emitting medium 25 and supplies pumping light (P) to the light-emitting medium 25. The light-emitting medium 25 includes a distributed Bragg reflector (“DBR”) mirror 22 and an active layer 23 formed sequentially on a substrate 21. The DBR mirror 22 has a plurality of alternately stacked layers having different refractive indexes, forming a mirror layer with high reflectivity.

The active layer 23 has a multi-quantum well (“MQW”) structure with a plurality of quantum wells (“QW”) arranged at regular intervals. The active layer 23 is excited by the pumping light (P) and emits predetermined wavelength of light. The above-structured light-emitting medium 25 is attached to a heat spreader 27 with high heat conducting characteristics. The heat generated in the light-emitting medium 25 is dissipated by the heat spreader 27. The light emitted from the light-emitting medium 25 is amplified as it resonates between the DBR mirror 22 and the external cavity mirror 50, and ultimately exits as laser light (L) through the external cavity mirror 50.

A birefringence filter 40, for selectively passing light of a predetermined wavelength, and a second harmonic generation (“SHG”) crystal 30 for creating a second harmonic wave having twice as many frequencies as the fundamental light from the light-emitting medium 25, are disposed between the light-emitting medium 25 and the external cavity mirror 50. There is a proportional relationship between the frequency conversion efficiency of an SHG crystal and the energy concentration of incident light. Thus, in order to increase the frequency conversion efficiency of the SHG crystal 30, it is preferable that the beam diameter of the light is focused into a minimal area. However, in the prior art, there is no separate focusing medium provided to focus the light incident on the SHG crystal 30, and the SHG crystal 30 is remotely disposed from the light-emitting medium 25, so that as the light emitted from the light-emitting medium 25 proceeds towards the SHG crystal 30, its beam diameter gradually increases so that the frequency conversion efficiency of the SHG decreases.

Additionally, in the conventional VECSEL illustrated in FIG. 1, the light resonated between the DBR mirror 22 and the external cavity mirror 50 is incident perpendicularly on the surface of the light-emitting medium 25, whereas the pumping light (P) from the pump LD 10 is incident obliquely. Thus, in a surface of the light-emitting medium 25, the resonance region on which the light resonating between the DBR mirror 22 and the external cavity mirror 50 is incident and the light-emitting region formed by the light pumping do not completely coincide. In such a mismatching portion, it is difficult for light to resonate, so that safety and oscillating efficiency of the light-emitting medium 25 diminish.

### BRIEF SUMMARY OF THE INVENTION

An exemplary embodiment provides a vertical cavity surface emitting laser capable of increasing the frequency conversion efficiency of a second harmonic generation (“SHG”) crystal, in order to increase the output of the laser.

An exemplary embodiment provides a vertical cavity surface emitting laser capable of increasing the frequency conversion efficiency of the SHG crystal while also facilitating the alignment of components and able to be readily compacted.

In an exemplary embodiment, there is provided a vertical external cavity surface emitting laser (“VECSEL”) including a light-emitting device, a second harmonic generation (SHG) crystal and an external cavity mirror. The light-emitting device includes a mirror layer defining a resonance region, an active layer generating light, a heat spreader dissipating heat generated in the active layer, and a micro lens coupled to the heat spreader and having a convex outer surface to focus light. The second harmonic generation (“SHG”) crystal converts a frequency of light focused by the micro lens. The external cavity mirror transmits the light converted by the SHG crystal and outputs the transmitted light as laser light, while reflecting unconverted light back to the mirror layer to resonate the unconverted light.

In an exemplary embodiment, a pumping laser diode (“LD”) may be disposed at a rear of the light-emitting device to optically pump the active layer. The second harmonic generation crystal disposed between the light-emitting device and the external cavity mirror is linearly arranged in a straight line with the light-emitting device and the external cavity mirror.

In an exemplary embodiment, a birefringence filter may be included between the SHG crystal and the external cavity mirror, to selectively transmit light of a certain wavelength.

In an exemplary embodiment, the micro lens may have a spheric surface structure. The micro lens may have an aspheric surface structure. The micro lens may have an elliptical or an asymmetrical shape. The micro lens may change a light beam having a non-circular cross section generated by the active layer to a light beam having a circular cross section to supply to the SHG crystal.

In an exemplary embodiment, the external cavity mirror may have a concave surface. The external cavity mirror may have a flat surface.

In an exemplary embodiment, the second harmonic generation crystal may have an anti-reflective coating layer formed on a surface thereof facing the pump LD to prevent reflection of pumping light and to facilitate light transmission.

In an exemplary embodiment, the SHG crystal may include anti-reflective coating layers formed on sides thereof facing the light-emitting device and the external cavity mirror, the anti-reflective coating layers preventing reflection of the fundamental light and the converted light and facilitating light passing through the SHG crystal.

In an exemplary embodiment, the external cavity mirror may include a reflecting/transmitting coating layer formed on an inner surface thereof to selectively reflect and resonate the fundamental light and transmit the converted light externally. The external cavity mirror may include an anti-reflecting coating layer formed on an outer surface thereof, to prevent reflection of the converted light. The mirror layer may be a DBR mirror.

In an exemplary embodiment, the heat spreader may be coupled to the active layer. The heat spreader may be formed of a light transparent material to transmit the light generated by the active layer.

In an exemplary embodiment of a method of forming a vertical external cavity surface emitting laser (“VECSEL”), the method includes forming a light-emitting device, forming a second harmonic generation (“SHG”) crystal and forming an external cavity mirror. The light-emitting device includes a mirror layer defining a resonance region and an active layer generating light sequentially disposed on a substrate, a heat spreader disposed on the active layer, and a micro lens coupled to the heat spreader. The micro lens includes a convex outer surface and focus the light from the active layer. The second harmonic generation (“SHG”) crystal converts a frequency of the light focused by the micro lens. The external cavity mirror transmits light converted by the SHG crystal and outputs the transmitted light as laser light, and reflects unconverted light back to the mirror layer resonating the unconverted light. The light emitting device, the second harmonic generation crystal and the external cavity mirror are disposed linearly relative to each other.

### BRIEF DESCRIPTION OF THE DRAWINGS

The above and other features and advantages of the present invention will become more apparent by describing in detail exemplary embodiments thereof with reference to the attached drawings in which:

FIG. 1 is a vertical cross-sectional view of a conventional vertical external cavity surface emitting laser (“VECSEL”) of the prior art;

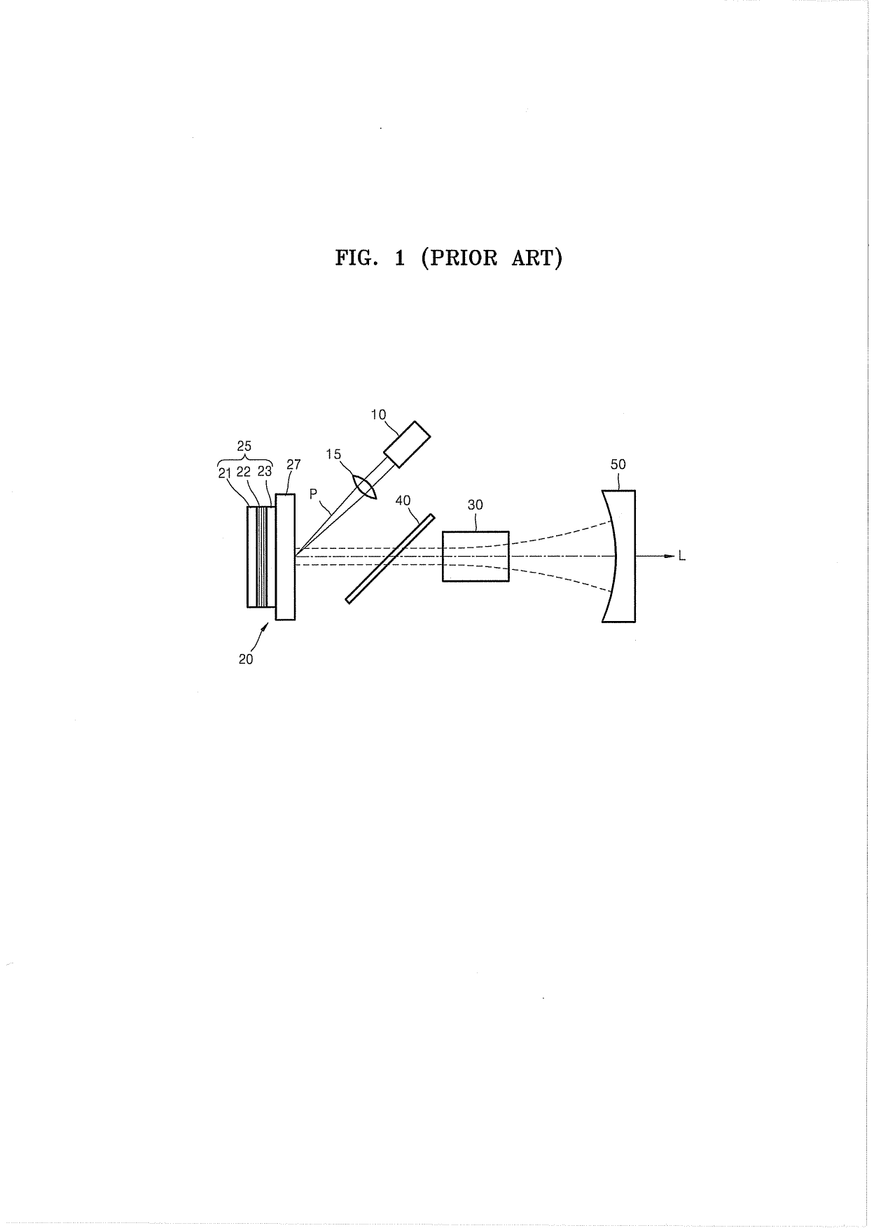

FIG. 2 is a vertical sectional view of an exemplary embodiment of a vertical external cavity surface emitting laser (“VECSEL”) according to the present invention; and

FIG. 3 is a vertical sectional view of another exemplary embodiment of a vertical external cavity surface emitting laser (“VECSEL”) according to the present invention.

### DETAILED DESCRIPTION OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “coupled to” another element or layer, the element or layer can be directly on or coupled to another element or layer or intervening elements or layers. In contrast, when an element is referred to as being “directly on” or “directly coupled to” another element or layer, there are no intervening elements or layers present. Like numbers refer to like elements throughout. As used herein, the term “and/or” includes any and all combinations of one or more of the associated listed items.

Spatially relative terms, such as “front”, “rear”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over or turned around, elements described as “rear” relative to other elements or features would then be oriented “front” relative to the other elements or features. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

The present invention will now be described more fully with reference to the accompanying drawings, in which exemplary embodiments of the invention are shown.

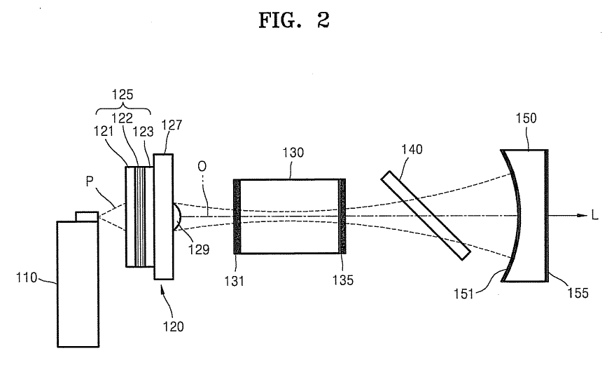

FIG. 2 is a vertical cross-sectional view of a vertical external cavity surface emitting laser (“VECSEL”) according to the present invention. Referring to FIG. 2, the vertical external cavity surface emitting laser includes a light-emitting device 120 for generating light of a predetermined wavelength, a pump laser diode (“LD”) 110 for supplying pumping light (P) from the rear of the light-emitting device 120 and an external cavity mirror 150 disposed to face the light-emitting device 120 at a predetermined distance therefrom. The external cavity mirror 150 allows a portion of the light emitted by the light-emitting device 120 through to be outputted as laser light (L) and reflects an other portion of light back to the light-emitting device 120, creating a resonance condition.

A second harmonic generation (“SHG”) crystal 130 for doubling the frequency of light emitted by the light-emitting device 120, and a birefringence filter 140 for selectively transmitting light of certain wavelengths are arranged between the light-emitting device 120 and the external cavity mirror 150. The second harmonic generation (“SHG”) crystal 130, the birefringence filter 140, the light-emitting device 120 and the external cavity mirror 150 may hereinafter be referred to as “elements” of the vertical external cavity surface emitting laser.

The VESCEL of the illustrated embodiment is an end pump type laser device with the pump LD 110 to a rear side of the light-emitting device 120. In one exemplary embodiment, the pump LD 110 supplies pumping light P having a wavelength of about 808 nanometers (nm) to a front of the light-emitting device 120 (e.g., opposite to the rear side), in order to excite an active layer 123 of the light-emitting device 120. An anti-reflective coating layer 131 may be formed on a side of the SGH crystal 130 facing the pump LD 110, to minimize reflection of the pumping light P and facilitate light transmission.

The light-emitting device 120 includes a light-emitting medium 125 having a mirror layer 122 and the active layer 123 stacked in sequence on a substrate 121, a heat spreader 127 and a micro lens 129 attached to the light-emitting medium 125 (e.g., on the front side). The mirror layer 122 defines a resonance region together with the external cavity mirror 150. The light generated by the active layer 123 resonates between the mirror layer 122 and the external cavity mirror 150 to become amplified. The mirror layer 122 may be formed of a distributed Bragg reflector (“DBR”), which is a multi layer structure having a plurality of layers with high and low refractive indexes alternately stacked. In an exemplary embodiment, each refractive index layer of the DBR may have a thickness of about ¼ of the respective wavelengths generated by the active layer 123.

The active layer 123 may be formed as a multi-quantum well (“MQW”) structure that has quantum wells (“QW”) arranged at substantially regular intervals, and barrier layers interposed between the QWs. In one exemplary embodiment, the active layer 123 generates light having a longer wavelength than that of the pumping light P, such as where the pumping light P having a wavelength of 808 nm. The light generated by the active layer 123 is specifically dependant on the compound material that the active layer 123 includes and is formed of. In an exemplary embodiment, the active layer may generate light having wavelengths between 920 nm and 1064 nm.

Heat generated from the active layer 123 is dissipated by the heat spreader 127, reducing or effectively preventing heat damage to the active layer 123. The heat spreader 127 may be formed of a material having high heat conductivity or of a material having both high heat conductivity and high light permeability to allow light generated by the active layer 123 to pass through. In one exemplary embodiment, the heat spreader 127 may be formed of carbon silicate SiC, diamond, aluminum nitride, or the like. The heat spreader may include a light transparent material for transmitting the light generated by the active layer.

The heat spreader 127 may be coupled to the light-emitting medium 125. In one exemplary embodiment, the heat spreader 127 to which the micro lens 129 has been separately bonded may be coupled to the light-emitting medium 125, thereby forming the light-emitting device 120 shown in FIG. 2.

The micro lens 129 is a convex lens that focuses initial (or fundamental) light generated by the active layer 123. The initial light that is focused after passing through the micro lens 129 is supplied to the front of the SHG crystal 130. The frequency conversion efficiency of the SHG crystal 130 is dependent on the energy of the incident light to the SHG crystal 130. The beam diameter of the light incident on the SHG crystal 130 after passing through the micro lens 129 is minimized, so that the frequency conversion efficiency of the SHG crystal 130 is increased and the light output by the SHG crystal 130 may result in increased visible radiation of blue or green light.

In exemplary embodiments, the micro lens 129 may be formed as a spheric or an aspheric lens. Spheric lenses may be relatively easier and less expensive to manufacture. The aspheric micro lens may shape the light in circular waves and thereby contributing to the increased frequency conversion efficiency of the SHG crystal 130.

In the illustrated embodiment, the pumping light P emitted from the pump LD 110 is incident on the active layer 123 at a predetermined emission angle, so that the shape of a spot through which the light is incident on the active layer 123 is not a circle. When divergence speeds of the pumping light P in a vertical axis and a horizontal axis are different, the pumping light P is not a circular beam but an elliptical one. Therefore, there is a relatively high probability of non-circular light being outputted from the active layer 123 that is excited by a non-circular pumping light.

The micro lens 129 is formed as an aspheric lens that shapes the non-circular light outputted from the active layer 123 into circular or near-circular light to be provided to the SHG crystal 130. The shaped circular or near-circular light can positively contribute to the conversion efficiency of the SHG crystal 130. In exemplary embodiments, the aspheric lens may be manufactured in an elliptical or asymmetric shape to correspond to the shape of the pumping light P. The micro lens 129 may be formed in a plano-convex shape. A flat side of the micro lens 129 may be attached, such as by bonding, to the heat spreader 127 or may be directly molded onto the heat spreader 127. When the micro lens 129 is coupled to the heat spreader 127, compared to a case where the micro lens 129 is made separately from the heat spreader 127 or made separately from the heat spreader 127 attached to the light-emitting medium 125, optical alignment in a highly integrated resonator can be achieved with substantially more facility or capability, with the use of fewer parts, and allowing for more compact resonator designs.

The light focused by the micro lens 129 enters the SHG crystal 130. The SHG crystal 130 transforms received light with a fundamental frequency into light having double the frequency, such that infrared light can be converted into visible light. In one exemplary embodiment, infrared light having a wavelength of 920 nm and 1064 nm can be converted by the SHG crystal 130 to visible blue light and green light having respective wavelengths of 460 nm and 532 nm.

Anti-reflectance coating layers 131 and 135 may be respectively formed on the front and rear surfaces of the SHG crystal 130 (through which an optical axis O of the light passes) in order to facilitate the transmission of light through the SHG crystal 130 and reduce or effectively prevent reflection of the light. A birefringence filter 140 disposed obliquely in the optical path of the light emitted by the SHG crystal 130 selectively filters certain wavelengths of light. By excluding other wavelengths of light, the birefringence filter 140 creates a sharp spectrum distribution of a certain wavelength of light.

The external cavity mirror 150 provides a predetermined resonating space together with the mirror layer 122 of the light-emitting device 120. The external cavity mirror 150 transmits light whose frequency has been converted by the SHG crystal 130 to the outside, and conversely, reflects light whose frequency has not been converted back to the light-emitting device 120 to perform resonating.

The external cavity mirror 150 has a reflective/transmitting coating layer 151 that selectively reflects or transmits the light depending on the wavelength, formed on the surface (e.g., inner surface) of the external cavity mirror 150 facing the light-emitting device 120. The external cavity mirror 150 may also have an anti-reflective coating layer 155 formed on its outer surface (e.g., outer surface) to reduce or effectively prevent reflection of light whose frequency has been changed.

The external cavity mirror 150 of the illustrated embodiment may be formed in a concave shape having a predetermined curvature. The light reflected by the external cavity mirror 150 is proximal to the optical axis O and converges as it progresses towards the light-emitting device 120. The light converges to a range corresponding to a light-emitting region formed by the active layer 123. When the resonance region of the light-emitting device 120 into which the light reflected by the external cavity mirror 150 enters is larger than the light-emitting region, amplification of light generated in the regions outside the light-emitting region is difficult. Thus, the stability of a resonator is decreased, and the resonated light is wasted, thus wasting the energy consumed for light pumping and reducing the output light intensity of the laser. The external cavity mirror 150 of the illustrated embodiment maintains the stability of the resonator.

In the vertical external cavity surface emitting laser of the illustrated embodiment, the components are arranged in substantially a single (e.g., linear) line to form a structure with a straight beam axis. In this linearly structured laser device, when compared to other devices having a structure in which components are arranged along different lines with predetermined interlimb angles therebetween so that the optical axis is bent at least once, installation space is saved and it is easy to make the resonator compact. Advantageously, it is relatively easier to align optical components in a highly integrated format due to the simple arrangement structure.

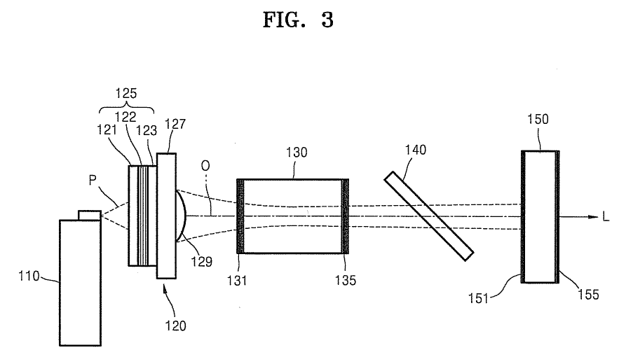

FIG. 3 is a vertical sectional view of another exemplary embodiment of a vertical external cavity surface emitting laser (“VECSEL”) according to the present invention. Like elements illustrated in FIG. 2 and those elements that perform the same functions are assigned the same reference numerals in FIG. 3.

Referring to FIG. 3, the VECSEL includes a pump LD 110 for pumping light, a light-emitting device 120 which is excited by the pumping light P and generates initial or fundamental light, an external cavity mirror 150 disposed to face the light-emitting device 120 at a predetermined distance therefrom and performing resonance therebetween, an SHG crystal 130 for converting frequencies, a birefringence filter 140 for selectively transmitting light of certain wavelengths disposed between the light-emitting device 120 and the external cavity mirror 150. The VECSEL illustrated in FIG. 3 is also an end-pump type laser device that is supplied with pumping light from a rear of the light-emitting device 120. The end-pump type laser device of the illustrated embodiment includes the pump LD 110, and has optical components (e.g., elements) arranged linearly between the light-emitting device 120 and the external cavity mirror 150.

The light-emitting device 120 has a substrate 121, a DBR mirror layer 122 sequentially stacked on the substrate 121, and an active layer 123 having a MQW structure. Heat emitted from the active layer 123 is dissipated by a heat spreader 127, and a micro lens 129 is provided to focus the light of a predetermined wavelength generated by the active layer 123.

The micro lens 129 also has a convex structure for supplying a highly-concentrated focused beam to the SHG crystal 130. To convert the light that enters the SHG crystal 130 into a circular beam, an aspheric lens may be used. However, the micro lens 129 illustrated in FIG. 3, when compared to the micro lens 129 illustrated in FIG. 2, is adjusted in its curvature to have a relatively low refractive power.

The beam that passes through the micro lens 129 with the comparatively low refractive power enters the SHG crystal 130 at a gently convergent angle, and the beam passes through the birefringence filter 140 which transmits light of certain wavelengths to the external cavity mirror 150. The external cavity mirror 150 provides a resonance region together with the DBR mirror layer 122 of the light-emitting device 120, and the light generated from the light-emitting device 120 is amplified as it moves back and forth within the resonance region. Light that is resonated after passing through the micro lens 129 with low refractive power moves back and forth in the resonance region in form of substantially parallel beam. Therefore, the shape of the external cavity mirror 150 of the illustrated embodiment of the present invention is different from that of the external cavity mirror 150 illustrated in FIG. 2 and may be a flat surfaced structure. The light reflected by the external cavity mirror 150 is incident on the light-emitting device 120 along an optical axis O, for stable light amplification.

When the external cavity mirror 150 is formed to have a flat surfaced structure instead of a concave shaped structure, a process of manufacturing a concave shaped structure is not required. Also, a speed of a process of coating the surface of the external cavity mirror 150 can be increased when the external cavity mirror 150 includes a flat surfaced structure. Therefore, the process of coating can be performed with relatively high precision, such as having a thickness and material of the coating layer be substantially evenly distributed regardless of location across the (inner) flat surface of the external cavity mirror 150.

The vertical external cavity surface emitting laser of the illustrated embodiment is provided with a micro lens for focusing light incident to a SHG crystal. Advantageously, the frequency conversion efficiency of the SHG crystal can be increased. Also, the micro lens is integrally formed as part of a light-emitting medium and a heat spreader (and not as a separate component), thereby reducing the number of components and allowing a resonator to be designed more compactly, obviating the need for a separate alignment of the microlens.

The vertical external cavity surface emitting laser of the illustrated embodiment is provided with a pump LD to the rear of the light-emitting device to arrange the components in a straight line, so that alignment of the components is easier.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A vertical external cavity surface emitting laser (“VECSEL”) comprising:
a light-emitting device comprising a mirror layer defining a resonance region, an active layer generating light, a heat spreader dissipating heat generated in the active layer and a micro lens coupled to the heat spreader and including a convex outer surface, the microlens focusing the light;
a second harmonic generation (“SHG”) crystal converting a frequency of the light focused by the micro lens; and
an external cavity mirror transmitting light converted by the SHG crystal and outputting the transmitted light as laser light, and reflecting unconverted light back to the mirror layer resonating the unconverted light.

2. The vertical external cavity surface emitting laser of claim 1, further comprising a pumping laser diode (“LD”) disposed at a rear of the light-emitting device, the pumping laser diode optically pumping the active layer.

3. The vertical external cavity surface emitting laser of claim 1, wherein the second harmonic generation crystal is disposed between the light-emitting device and the external cavity mirror are linearly arranged.

4. The vertical external cavity surface emitting laser of claim 1, further comprising a birefringence filter disposed between the second harmonic generation crystal and the external cavity mirror, the birefringence filter selectively transmitting light of a certain wavelength.

5. The vertical external cavity surface emitting laser of claim 1, wherein the micro lens has a spheric surface structure.

6. The vertical external cavity surface emitting laser of claim 1, wherein the micro lens has an aspheric surface structure.

7. The vertical external cavity surface emitting laser of claim 6, wherein the micro lens has an elliptical shape.

8. The vertical external cavity surface emitting laser of claim 6, wherein the micro lens has an asymmetrical shape.

9. The vertical external cavity surface emitting laser of claim 6, wherein the micro lens is configured to change a light beam having a non-circular cross section generated by the active layer to a light beam having a circular cross section, the light beam of circular cross section being supplied to the SHG crystal.

10. The vertical external cavity surface emitting laser of claim 1, wherein the external cavity mirror includes a concave surface facing the second harmonic generation crystal.

11. The vertical external cavity surface emitting laser of claim 1, wherein the external cavity mirror includes a flat surface facing the second harmonic generation crystal.

12. The vertical external cavity surface emitting laser of claim 1, wherein the second harmonic generation crystal comprises anti-reflective coating layers formed on surfaces facing the light emitting device and the external cavity mirror, the anti-reflective coating layers preventing reflection of the light from the active layer and the converted light, and facilitating light passing through the second harmonic generation crystal.

13. The vertical external cavity surface emitting laser of claim 1, wherein the external cavity mirror comprises a reflecting/transmitting coating layer formed on an inner surface thereof, the reflecting/transmitting coating layer selectively reflecting and resonating the light from the active layer and transmitting the converted light externally.

14. The vertical external cavity surface emitting laser of claim 1, wherein the external cavity mirror comprises an anti-reflecting coating layer formed on an outer surface thereof, the anti-reflecting coating layer preventing reflection of the converted light.

15. The vertical external cavity surface emitting laser of claim 1, wherein the mirror layer is a DBR mirror.

16. The vertical external cavity surface emitting laser of claim 1, wherein the heat spreader is coupled to the active layer.

17. The vertical external cavity surface emitting laser of claim 1, wherein the heat spreader includes a light transparent material, the heat spreader transmitting the light generated by the active layer.

18. A method of forming a vertical external cavity surface emitting laser (“VECSEL”), the method comprising:
forming a light-emitting device including a mirror layer defining a resonance region and an active layer generating light sequentially disposed on a substrate, disposing a heat spreader on the active layer, and coupling a micro lens to the heat spreader, the micro lens including a convex outer surface and focusing the light;
forming a second harmonic generation (“SHG”) crystal converting a frequency of the light focused by the micro lens; and
forming an external cavity mirror transmitting light converted by the SHG crystal and outputting the transmitted light as laser light, and reflecting unconverted light back to the mirror layer resonating the unconverted light;
wherein the light emitting device, the second harmonic generation crystal and the external cavity mirror are disposed linearly relative to each other.
